(19) United States
(12) Patent Application Publication
(10) Pub. No.: US 2026/0076007 A1
(43) Pub. Date: Mar. 12, 2026

(54) DISPLAY APPARATUS

(71) Applicant: LG Display Co., Ltd., Seoul (KR)

(72) Inventors: ChungHwan AN, Goyang-si (KR); Jinho KIM, Paju-si (KR); Dojin KIM, Seoul (KR); Jongha JAE, Uiwang-si (KR)

(73) Assignee: LG Display Co., Ltd., Seoul (KR)

(21) Appl. No.: 19/217,955

(22) Filed: May 23, 2025

(30) Foreign Application Priority Data
Sep. 9, 2024 (KR) 10-2024-0122679

(51) Int. Cl. H10H 29/41; H10H 29/37; H10H 29/80

(52) U.S. Cl. CPC H10H 29/41; H10H 29/37; H10H 29/8325

(57) ABSTRACT

A display apparatus includes a substrate in which a plurality of pixels including a plurality of sub pixels is defined, a plurality of transistors on the substrate, an insulating layer on the substrate, an adhesive layer on the insulating layer, and a plurality of light emitting diodes on the adhesive layer in each of the plurality of sub pixels. The insulating layer includes a plurality of holes disposed in each of the plurality of pixels. The plurality of holes includes a plurality of first holes, a plurality of second holes, and a plurality of third holes. The plurality of first holes overlap the plurality of light emitting diodes. The plurality of second holes enclose the plurality of first holes on a plane, and the plurality of third holes includes a hole in the outermost periphery in a first direction.

### CROSS-REFERENCE TO RELATED APPLICATIONS

This application claims the priority of Korean Patent Application No. 10-2024-0122679 filed on Sep. 9, 2024, in the Korean Intellectual Property Office, the disclosure of which is incorporated herein by reference.

### Technical Field

The present disclosure relates to a display apparatus, and more particularly, to a display apparatus using a light emitting diode (LED).

### Discussion of the Related Art

As display apparatus which are used for a monitor of a computer, a television, a cellular phone, or the like, there are an organic light emitting display (OLED) device which is a self-emitting device, a liquid crystal display (LCD) device which requires a separate light source, and the like.

An applicable range of the display apparatus is diversified to personal digital assistants as well as monitors of computers and televisions and a display apparatus with a large display area and a reduced volume and weight is being studied.

Further, recently, a display apparatus including a light emitting diode (LED) is attracting attention as a next generation display apparatus. Since the LED is formed of an inorganic material, rather than an organic material, reliability is excellent so that a lifespan thereof is longer than that of the liquid crystal display apparatus or the organic light emitting display apparatus. Further, the LED has a fast lighting speed, excellent luminous efficiency, and a strong impact resistance so that a stability is excellent and an image having a high luminance can be displayed.

### SUMMARY

Accordingly, embodiments of the present disclosure are directed to a display apparatus that substantially obviates one or more of the problems due to limitations and disadvantages of the related art.

An aspect of the present disclosure is to provide a display apparatus with a reduced thickness deviation of an adhesive layer to which a light emitting diode is attached.

Another aspect of the present disclosure is to provide a display apparatus in which an over-transferring problem during a transfer process is improved to reduce a manufacturing cost.

Still another aspect of the present disclosure is to provide a display apparatus in which a selectivity of transfer and non-transfer of a light emitting diode is improved.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a substrate in which a plurality of pixels including a plurality of sub pixels is defined, a plurality of transistors disposed on the substrate, an insulating layer disposed on the substrate, an adhesive layer disposed on the insulating layer, and a plurality of light emitting diodes disposed on the adhesive layer in each of the plurality of sub pixels, wherein the insulating layer includes a plurality of holes disposed in each of the plurality of pixels, the plurality of holes includes a plurality of first holes, a plurality of second holes, and a plurality of third holes, the plurality of first holes is disposed so as to overlap the plurality of light emitting diodes, the plurality of second holes is disposed so as to enclose the plurality of first holes on a plane, and the plurality of third holes includes a hole disposed in the outermost periphery in a first direction, among the plurality of holes.

In another aspect, a display apparatus comprises a substrate in which a pixel including a plurality of sub pixels is defined, an insulating layer disposed on the substrate, a plurality of reflection electrodes disposed on the insulating layer, an adhesive layer disposed on the plurality of reflection electrodes, and a plurality of light emitting diodes disposed on the adhesive layer in each of the plurality of sub pixels, wherein the insulating layer includes a plurality of first holes overlapping the plurality of reflection electrodes, a plurality of second holes overlapping the plurality of reflection electrodes and a plurality of third holes which does not overlap the plurality of reflection electrodes.

Other detailed matters of the exemplary embodiments are included in the detailed description and the drawings.

According to the present disclosure, the thickness of the adhesive layer is uniformized to optimize the process.

According to the present disclosure, a pressure of a non-transferred area is reduced to suppress over-transferring.

According to the present disclosure, a selectivity of transfer and non-transfer of the light emitting diode is improved to reduce a process cost and a product cost.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic diagram of a display apparatus according to an exemplary embodiment of the present disclosure;

FIG. 2A is a partial cross-sectional view of a display apparatus according to an exemplary embodiment of the present disclosure;

FIG. 2B is a perspective view of a tiling display apparatus according to an exemplary embodiment of the present disclosure;

FIG. 3 is an enlarged plan view of a display apparatus according to an exemplary embodiment of the present disclosure;

FIG. 4 is an enlarged plan view of a display apparatus according to an exemplary embodiment of the present disclosure;

FIG. 5 is a cross-sectional view of a display apparatus taken along A-A′ of FIG. 3;

FIG. 6 is a cross-sectional view of a display apparatus taken along B-B′ of FIG. 4;

FIG. 7 is a cross-sectional view of a display apparatus taken along C-C′ of FIG. 4;

FIGS. 8A to 8D are process diagrams for explaining a manufacturing method of a display apparatus according to an exemplary embodiment of the present disclosure; and

FIG. 9 is an enlarged plan view of a display apparatus according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When an element or layer is disposed “on” another element or layer, another layer or another element may be interposed directly on the other element or layer or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

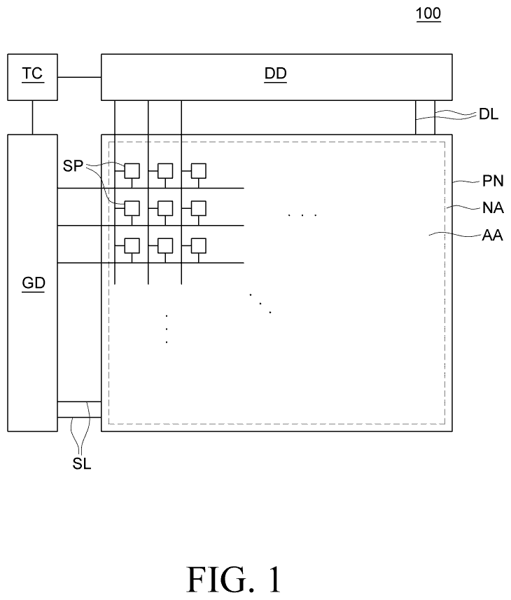

FIG. 1 is a schematic diagram of a display apparatus according to an exemplary embodiment of the present disclosure. In FIG. 1, for the convenience of description, among various components of the display apparatus 100, only a display panel PN, a gate driver GD, a data driver DD, and a timing controller TC are illustrated.

Referring to FIG. 1, the display apparatus 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP is connected to a high potential power line, a low potential power line, and a reference line.

In the display panel PN, an active area AA and a non-active area NA enclosing the active area AA may be defined.

The active area AA is an area in which images are displayed in the display apparatus 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP form one pixel PX. In each of the plurality of sub pixels SP, a light emitting diode and a thin film transistor for driving the light emitting diode may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED).

In the active area AA, a plurality of signal lines which transmits various signals to the plurality of sub pixels SP is disposed. For example, the plurality of signal lines includes a plurality of data lines DL which supplies a data voltage to each of the plurality of sub pixels SP and a plurality of scan lines SL which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed. The non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and are electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel is increased.

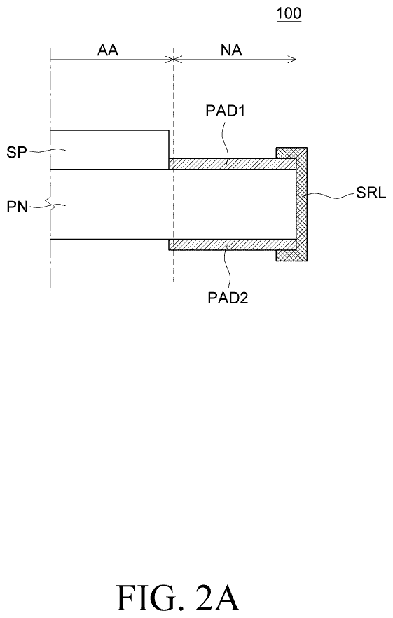

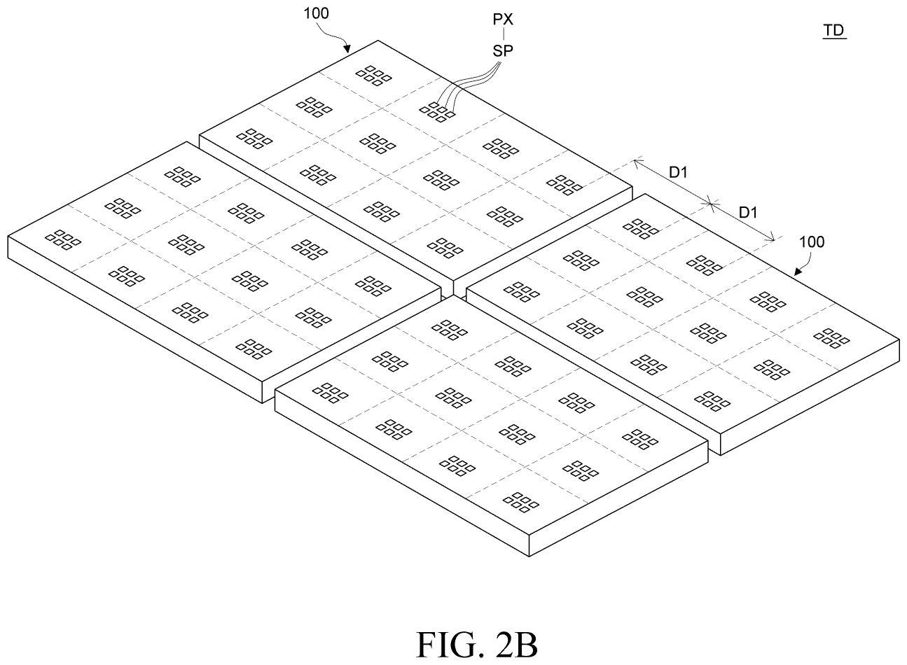

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display apparatus according to an exemplary embodiment of the present disclosure. FIG. 2B is a perspective view of a tiling display apparatus according to an exemplary embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL electrically connects the first pad electrode PAD1 on the front surface of the display panel PN and the second pad electrode PAD2 on the rear surface of the display panel PN. Therefore, a signal from a driving component on the rear surface of the display panel PN is transmitted to the plurality of sub pixels SP through the second pad electrode PAD2, the side line SRL, and the first pad electrode PAD1. Accordingly, a signal transmitting path is formed from the front surface of the display panel PN to the side surface and the rear surface to minimize an area of the non-active area NA of the display panel PN.

Referring to FIG. 2B, a tiling display apparatus TD having a large screen size may be implemented by connecting a plurality of display apparatus 100. At this time, when the tiling display apparatus TD is implemented using a display apparatus 100 with a minimized bezel as illustrated in FIG. 2A, a seam area in which an image is not displayed between the display apparatus 100 is minimized so that a display quality may be improved.

For example, the plurality of sub pixels SP forms one pixel PX and a distance D1 between an outermost pixel PX of one display apparatus 100 and an outermost pixel PX of another display apparatus 100 adjacent to the one display apparatus 100 may be implemented to be equal to a distance D1 between pixels PX in one display apparatus 100. Accordingly, the interval of the pixels PX between the display apparatus 100 is constantly configured to minimize the seam area.

However, FIGS. 2A and 2B are illustrative so that the display apparatus 100 according to the exemplary embodiment of the present disclosure may be a general display apparatus with a bezel, but is not limited thereto.

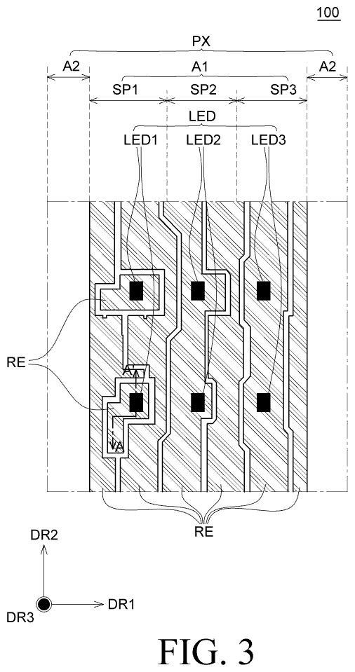

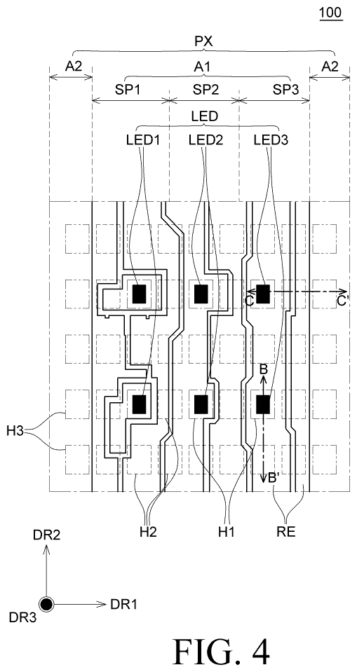

FIG. 3 is an enlarged plan view of a display apparatus according to an exemplary embodiment of the present disclosure. FIG. 4 is an enlarged plan view of a display apparatus according to an exemplary embodiment of the present disclosure. FIGS. 3 and 4 are enlarged plan views of one pixel PX of the display apparatus 100 according to an exemplary embodiment of the present disclosure. In FIG. 3, only a plurality of reflection electrodes RE and a plurality of light emitting diodes LED are illustrated. In FIG. 4, only a plurality of reflection electrodes RE, a plurality of light emitting diodes LED, and a plurality of holes H of an insulating layer are illustrated. In FIG. 4, for the convenience of description, the plurality of reflection electrodes RE is represented with a solid line and the plurality of holes H is represented with a dotted line.

Referring to FIGS. 3 and 4, the display panel PN includes a plurality of pixels PX which is formed by a plurality of sub pixels SP. Each of the plurality of sub pixels SP includes a light emitting diode LED and a pixel circuit to independently emit light. One pixel PX includes one or more first sub pixels SP1, one or more second sub pixels SP2, and one or more third sub pixels SP3. The first sub pixel SP1 is a red sub pixel, the second sub pixel SP2 is a green sub pixel, and the third sub pixel SP3 is a blue sub pixel, but they are not limited thereto.

The first sub pixels SP1, the second sub pixels SP2, and the third sub pixels SP3 of the plurality of sub pixels SP are disposed along a first direction DR1.

Each of the plurality of pixels PX includes a first area A1 and a second area A2.

The first area A1 includes a first sub pixel SP1, a second sub pixel SP2, and a third sub pixel SP3. For example, the first area A1 may be an area overlapping the plurality of reflection electrodes RE.

The second area A2 is disposed in an outer edge area of the pixel PX, outward from the first area A1. For example, the second areas A2 are disposed on both sides of the first area A1. For example, the second area A2 is disposed to be adjacent to the first sub pixel SP1 and the third sub pixel SP3, among the plurality of sub pixels SP. Therefore, the second area A2 is disposed to be spaced apart from the second sub pixel SP2 with the first sub pixel SP1 therebetween and is disposed to be spaced apart from the second sub pixel SP2 with the third sub pixel SP3 therebetween.

The second area A2 may be an area which does not overlap the plurality of reflection electrodes RE. When the plurality of reflection electrodes RE is disposed to be spaced apart from each other along the first direction DR1 while extending in a second direction DR2 different from the first direction DR1, the second area A2 extends in the second direction DR2 and is disposed on both sides of the plurality of reflection electrodes RE along the first direction DR1. The second direction DR2 can be perpendicular to the first direction.

Referring to FIGS. 3 and 4, the plurality of reflection electrodes RE is disposed in an area corresponding to the pixel PX. The reflection electrode RE is a configuration which reflects light emitted from the plurality of light emitting diodes LED to the top of the substrate 110 and is formed with a shape corresponding to each of the plurality of sub pixels SP. The plurality of reflection electrodes RE is disposed so as to cover the most area of one sub pixel SP. The plurality of reflection electrodes RE reflects the light emitted from the light emitting diode LED and is also used as an electrode which electrically connects the light emitting diode LED and the pixel circuit.

For example, the plurality of reflection electrodes RE includes reflection electrodes RE corresponding to the first sub pixel SP1, the second sub pixel SP2, and the third sub pixel SP3.

Further, the plurality of reflection electrodes RE includes a reflection electrode RE which is electrically connected to a driving transistor of each of the first sub pixel SP1, the second sub pixel SP2, and the third sub pixel SP3 and a reflection electrode RE which is connected to a power line of each of the first sub pixel SP1, the second sub pixel SP2, and the third sub pixel SP3.

In the meantime, each of the plurality of reflection electrodes RE extends in the second direction DR2 and overlaps the plurality of sub pixels SP disposed along the second direction DR2.

A plurality of light emitting diodes LED is disposed in the plurality of sub pixels SP. The plurality of light emitting diodes LED includes a first light emitting diode LED1, a second light emitting diode LED2, and a third light emitting diode LED3. The first light emitting diode LED1 is disposed in the first sub pixel SP1, the second light emitting diode LED2 is disposed in the second sub pixel SP2, and the third light emitting diode LED3 is disposed in the third sub pixel SP3. The first light emitting diode LED1 is a red light emitting diode, the second light emitting diode LED2 is a green light emitting diode, and the third light emitting diode LED3 is a blue light emitting diode, but the present disclosure is not limited thereto.

The plurality of light emitting diodes LED is disposed along the first direction DR1. For example, the first light emitting diodes LED1, the second light emitting diodes LED2, and the third light emitting diodes LED3 are disposed along the first direction DR1.

One pair of light emitting diodes LED which emit the same color may be disposed in one sub pixel SP. For example, one pair of first light emitting diodes LED1 is disposed in the first sub pixel SP1. One pair of first light emitting diodes LED1 is disposed along the second direction DR2. One pair of second light emitting diodes LED2 is disposed in the second sub pixel SP2. One pair of second light emitting diodes LED2 is disposed along the second direction DR2. One pair of third light emitting diodes LED3 is disposed in the third sub pixel SP3. One pair of third light emitting diodes LED3 is disposed along the second direction DR2.

In the meantime, each of the plurality of light emitting diodes LED has a long side in the second direction DR2. For example, when the light emitting diode LED has a structure in which a first electrode and a second electrode are included on both ends, the light emitting diode LED has a long side along a direction in which the first electrode and the second electrode are disposed, but is not limited thereto.

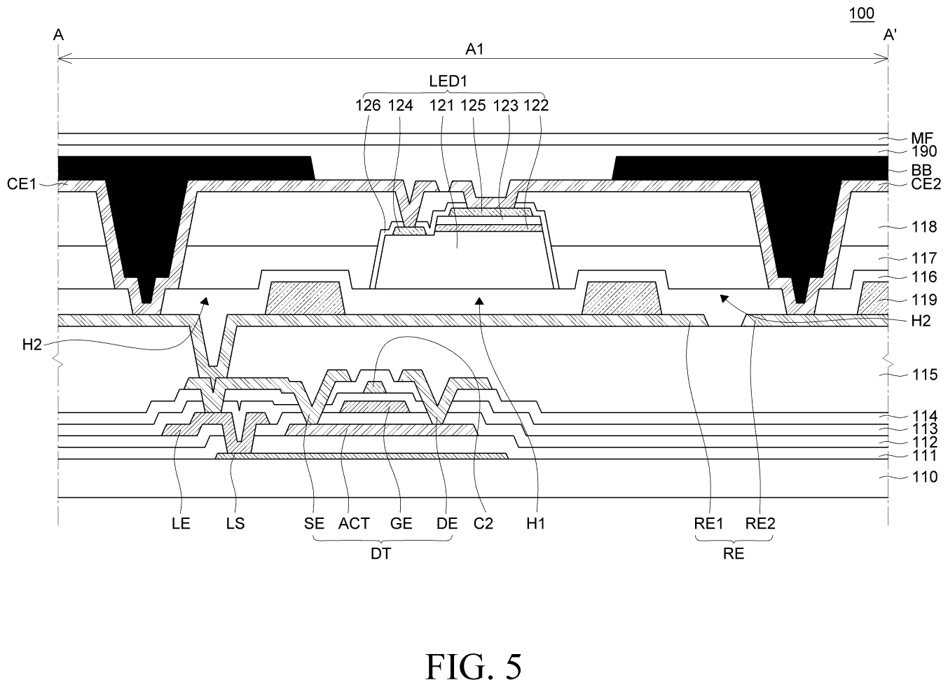

An insulating layer is disposed on the plurality of reflection electrodes RE in each of the plurality of pixels PX. The insulating layer includes a plurality of holes H. For example, the plurality of holes H exposes one surface of the plurality of reflection electrodes RE disposed therebelow. The insulating layer will be described in detail below with reference to FIGS. 5 to 7.

Each of the plurality of holes H has a short side in the first direction DR1 and a long side in the second direction DR2. For example, each of the plurality of holes H has a long side and a short side corresponding to a size of the plurality of light emitting diodes LED, but is not limited thereto.

The plurality of holes H includes a plurality of first holes H1, a plurality of second holes H2, and a plurality of third holes H3. The plurality of first holes H1 and the plurality of second holes H2 are disposed in the first area A1 and the plurality of third holes H3 is disposed in the second area A2.

In the first area A1, the plurality of first holes H1 is disposed. The plurality of light emitting diodes LED is disposed in each of the plurality of first holes H1. Further, the plurality of first holes H1 is disposed so as to overlap the plurality of reflection electrodes RE.

In the first area A1, the plurality of second holes H2 is disposed. The plurality of second holes H2 is disposed so as to enclose one light emitting diode LED. The plurality of second holes H2 is disposed so as to enclose the first hole H1. For example, the plurality of second holes H2 may be disposed along an outer peripheral area of the first hole H1. As another example, the plurality of second holes H2 may be disposed in an area corresponding to an edge and a vertex of each of the first holes H1. That is, the plurality of second holes H2 is disposed on both sides of the plurality of first holes H1 in the first direction DR1 and is disposed on both sides of the plurality of first holes H1 in the second direction DR2. Further, the second hole H2 is disposed in both sides of the plurality of first holes H1 in a diagonal direction.

At this time, when the plurality of light emitting diodes LED is disposed in one pixel PX, the second hole H2 and the first hole H1 are alternately disposed. For example, when light emitting diodes LED which emit different color light are disposed in one pixel PX and/or when light emitting diodes which emit same color light are disposed in one pixel PX, the second hole H2 and the first hole H1 are alternately disposed.

In the meantime, the plurality of second holes H2 may be continuously disposed along the first direction DR1 and/or the second direction DR2. For example, the plurality of second holes H2 which is disposed in an outermost peripheral side in one pixel PX may be continuously disposed along the first direction DR1 and/or the second direction DR2. For example, the second holes H2 are continuously disposed in a first column and the first holes H1 and the second holes H2 are alternately disposed in a second column, and the second holes H2 are continuously disposed in a third column. Further, the second holes H2 are continuously disposed in a first row and the first holes H1 and the second holes H2 are alternately disposed in a second row, and the second holes H2 are continuously disposed in a third row.

Accordingly, the plurality of second holes H2 may be disposed in an outer peripheral area of the pixel PX, outward from the plurality of first holes H1. For example, the plurality of second holes H2 disposed in the outermost periphery in one pixel PX is disposed so as to enclose all the plurality of first holes H1.

The plurality of second holes H2 is disposed so as not to overlap the plurality of light emitting diodes LED. The plurality of second holes H2 is disposed so as to overlap the plurality of reflection electrodes RE.

In the meantime, the plurality of second hole H2 includes all holes H excluding a hole H in which a light emitting diode LED is disposed, among the plurality of holes H disposed in the first area A1.

In the second area A2, the plurality of third holes H3 is disposed. The plurality of third holes H3 is disposed in an outer periphery of the pixel PX, outward from the plurality of second holes H2. The plurality of third holes H3 is disposed in an outermost periphery in each of the plurality of pixels PX, outward from the plurality of second holes H2. As another example, the plurality of third holes H3 is disposed in the outermost periphery of each pixel PX in the first direction DR1.

The plurality of third holes H3 is disposed in a position adjacent to a long side, between a long side and a short side of the plurality of second holes H2. Referring to FIG. 4, the plurality of third holes H3 is disposed in the outermost periphery of each pixel PX in the first direction DR1. Therefore, in the first direction DR1, the third hole H3, the second hole H2, and the first hole H1 are sequentially disposed along a center direction of a pixel PX from an outermost periphery of the pixel PX.

In the meantime, the plurality of third holes H3 may not be disposed in the outermost periphery of each pixel PX in the second direction DR2. For example, only the plurality of second holes H2 and the plurality of first holes H1, among the plurality of holes H, are disposed along the second direction DR2. Specifically, the plurality of second holes H2 is disposed in the outermost periphery of each pixel PX. Therefore, in the second direction DR2, the second hole H2 and the first hole H1 are sequentially disposed along a center direction of a pixel PX from an outermost periphery of the pixel PX or only the plurality of second holes H2 is disposed.

The plurality of third holes H3 is disposed so as not to overlap the plurality of light emitting diodes LED. The plurality of third holes H3 is disposed so as not to overlap the plurality of reflection electrodes RE. For example, in one pixel PX, the plurality of third holes H3 is disposed to be spaced apart from each other with the plurality of reflection electrodes RE therebetween.

In the meantime, it is illustrated in FIG. 4 that the plurality of holes H is spaced apart from each other with the same interval along the first direction DR1 and the plurality of holes H is spaced apart from each other with the same interval along the second direction DR2, but the present disclosure is not limited thereto. For example, intervals between the plurality of holes H may vary according to a placement of the pixels PX and a connection line of a signal line and a pixel PX disposed on the substrate 110.

Referring to FIG. 4, the plurality of holes H has the same size. However, it is not limited thereto and the plurality of holes H may have different sizes. For example, the plurality of first holes H1, the plurality of second holes H2, and the plurality of third holes H3 may have different sizes. Further, the plurality of second holes H2 includes second holes H2 having different sizes. For example, some second holes H2, among the plurality of second holes H2, extend to be longer than the other second hole H2 and include contact holes through which the plurality of reflection electrodes RE and the plurality of light emitting diodes LED are connected.

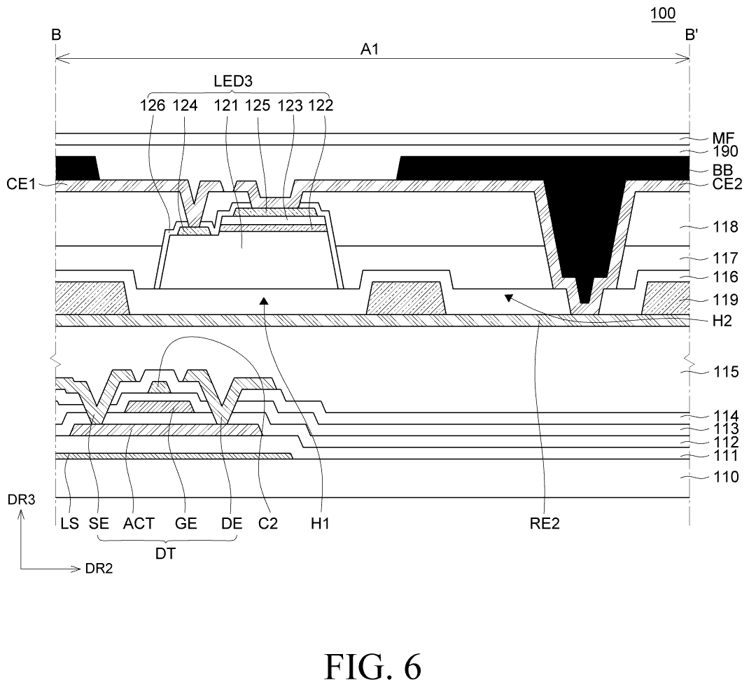

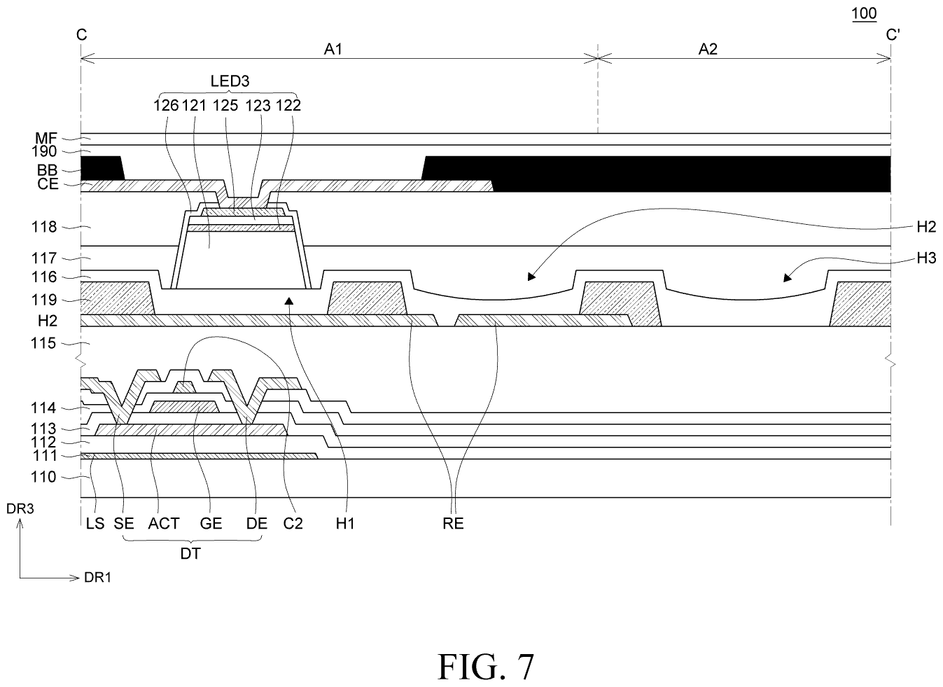

FIG. 5 is a cross-sectional view of a display apparatus taken along A-A′ of FIG. 3. FIG. 6 is a cross-sectional view of a display apparatus taken along B-B′ of FIG. 4. FIG. 7 is a cross-sectional view of a display apparatus taken along C-C′ of FIG. 4. Referring to FIGS. 5 to 7, in each of the plurality of sub pixels SP of the display panel PN of the display apparatus 100 according to the exemplary embodiment of the present disclosure, a substrate 110, a buffer layer 111, a gate insulating layer 112, a first interlayer insulating layer 113, a second interlayer insulating layer 114, a first planarization layer 115, an adhesive layer 116, a second planarization layer 117, a third planarization layer 118, an insulating layer 119, a bank BB, a protection layer 190, an optical film MF, a driving transistor DT, a light emitting diode LED, a plurality of reflection electrodes RE, a plurality of connection electrodes CE, a light shielding layer LS, and an auxiliary electrode LE are disposed.

First, the substrate 110 is a component for supporting various components included in the display apparatus 100 and may be formed of an insulating material. For example, the substrate 110 may be formed of glass or resin. Further, the substrate 110 may be configured to include a polymer or plastics or may be formed of a material having flexibility.

The light shielding layer LS is disposed in each of the plurality of sub pixels SP on the substrate 110. The light shielding layer LS blocks light incident onto an active layer ACT of the driving transistor DT to be described below from a lower portion the substrate 110. Light which is incident onto the active layer ACT of the driving transistor DT is blocked by the light shielding layer LS to minimize a leakage current. For example, the light shielding layer LS may be formed of molybdenum (Mo) having a high reflection efficiency, but is not limited thereto.

A buffer layer 111 is disposed on the substrate 110 and the light shielding layer LS. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 is disposed on the gate electrode GE. In the first interlayer insulating layer 113, a contact hole through which the source electrode SE and the drain electrode DE are connected to the active layer ACT is formed. The first interlayer insulating layer 113 is an insulating layer which protects components below the first interlayer insulating layer 113 and may be configured by a single layer or a double layer of silicon oxide (SiOx) or silicon nitride (SiNx), but is not limited thereto.

The capacitor electrode C2 is disposed on the first interlayer insulating layer 113. The capacitor electrode C2 is disposed so as to overlap the gate electrode GE with the first interlayer insulating layer 113 therebetween.

The second interlayer insulating layer 114 is disposed on the capacitor electrode C2. In the second interlayer insulating layer 114, a contact hole through which the source electrode SE and the drain electrode DE are connected to the active layer ACT is formed. The second interlayer insulating layer 114 is an insulating layer which protects components below the second interlayer insulating layer 114 and may be configured by a single layer or a double layer of silicon oxide (SiOx) or silicon nitride (SiNx), but is not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof. For example, the source electrode SE and the drain electrode DE are formed with a structure in which molybdenum (Mo), aluminum (Al), and molybdenum (Mo) are laminated, but are not limited thereto.

In the meantime, the source electrode SE and the drain electrode DE may have a thickness larger than that of the light shielding layer LS. The light shielding layer LS is disposed to be adjacent to the substrate 110 so that it is difficult for the light shielding layer to be formed with a large thickness. In contrast, the source electrode SE and the drain electrode DE are disposed above the substrate 110 more than the light shielding layer LS. Therefore, a thickness of each of the source electrode SE and the drain electrode DE may be larger than a thickness of the light shielding layer LS, but is not limited thereto.

In the meantime, in the present specification, it is described that the first interlayer insulating layer 113 and the second interlayer insulating layer 114, that is, a plurality of insulating layers is disposed between the gate electrode GE and the source electrode SE and the drain electrode DE. However, only one insulating layer may be disposed between the gate electrode GE and the source electrode SE and the drain electrode DE, but is not limited thereto.

As illustrated in the drawings, when a plurality of insulating layers, such as the first interlayer insulating layer 113 and the second interlayer insulating layer 114, is disposed between the gate electrode GE and the source electrode SE and the drain electrode DE, an electrode may be further formed between the first interlayer insulating layer 113 and the second interlayer insulating layer 114. The additionally formed electrode may form a capacitor with the other configuration disposed below first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized. Even though in the drawing, it is illustrated that the light shielding layer LS is connected to the source electrode SE, the light shielding layer LS may also be connected to the drain electrode DE, but is not limited thereto.

The first planarization layer 115 is disposed on the driving transistor DT. The first planarization layer 115 may planarize an upper portion of the substrate 110 on which the driving transistor DT is disposed. The first planarization layer 115 may be configured by a single layer or a double layer, and for example, may be formed of photoresist or an acrylic organic material, but is not limited thereto.

A plurality of reflection electrodes RE which is spaced apart from each other is disposed on the first planarization layer 115. The plurality of reflection electrodes RE electrically connects the light emitting diode LED to the plurality of power lines and the driving transistors DT and serves as reflectors which reflect light emitted from the light emitting diode LED to the upper portion of the light emitting diode LED. The plurality of reflection electrodes RE is formed of a conductive material having the excellent reflecting property to reflect light emitted from the light emitting diode LED toward the upper portion of the light emitting diode LED.

For example, the plurality of reflection electrodes RE may be configured by a conductive material such as copper (Cu), aluminum (Al), molybdenum (Mo), nickel (Ni), titanium (Ti), chrome (Cr), or an alloy thereof. In the meantime, the plurality of reflection electrodes RE is formed with a structure in which indium tin oxide (ITO), aluminum (Al), and molybdenum (Mo) are laminated, but is not limited thereto.

The thicknesses of the plurality of reflection electrodes RE may be larger than the thickness of the light shielding layer LS. The light shielding layer LS is disposed to be adjacent to the substrate 110 so that it is difficult for the light shielding layer to be formed with a large thickness. In contrast, each of the plurality of reflection electrodes RE may be disposed above the substrate 110 more than the light shielding layer LS. Therefore, a thickness of each of the plurality of reflection electrodes RE may be larger than the thickness of the light shielding layer LS.

The plurality of reflection electrodes RE may be formed of aluminum.

The plurality of reflection electrodes RE includes a first reflection electrode RE1 and a second reflection electrode RE2. The first reflection electrode RE1 electrically connects the driving transistor DT and the light emitting diode LED. The first reflection electrode RE1 is connected to the source electrode SE or the drain electrode DE of the driving transistor DT through a contact hole formed in the first planarization layer 115. The first reflection electrode RE1 may be electrically connected to the first electrode 124 of the light emitting diode LED through a first connection electrode CE1 to be described below. For example, referring to FIG. 5, the first reflection electrode RE1 is connected to the source electrode SE of the driving transistor DT. The first reflection electrode RE1 may be electrically connected to the first electrode 124 of the first light emitting diode LED1 through a first connection electrode CE1 to be described below.

The second reflection electrode RE2 may be electrically connected to the second electrode 125 of the plurality of light emitting diodes LED through a second connection electrode CE2 to be described below. For example, referring to FIG. 5, the second reflection electrode RE2 may be electrically connected to the second electrode 125 of the first light emitting diode LED1 through a second connection electrode CE2 to be described below. For example, referring to FIG. 6, the second reflection electrode RE2 may be electrically connected to the second electrode 125 of the third light emitting diode LED3 through the second connection electrode CE2 to be described below.

The insulating layer 119 is disposed on the first planarization layer 115 and the plurality of reflection electrodes RE. The first planarization layer 115 may be configured by a single layer or a double layer, and for example, may be formed of photoresist or an acrylic organic material, but is not limited thereto.

As described above, the insulating layer 119 includes a plurality of holes H. The plurality of holes H is disposed in each of the plurality of pixels PX. The plurality of holes H exposes a top surface of the plurality of reflection electrodes RE and/or the first planarization layer 115 disposed therebelow.

The plurality of holes H includes a plurality of first holes H1, a plurality of second holes H2, and a plurality of third holes H3.

Referring to FIGS. 6 and 7, the third light emitting diode LED3 may be disposed in the first hole H1. Further, the plurality of first holes H1 is disposed so as to overlap the first reflection electrode RE1 and the second reflection electrode RE2.

The plurality of second holes H2 is disposed in one sides and the other sides of the plurality of first holes H1. For example, referring to FIG. 6, the plurality of holes H2 is disposed in an area adjacent to the plurality of first holes H1 in the second direction DR2 and referring to FIG. 7, the plurality of second holes H2 is disposed in an area adjacent to the plurality of first holes H1 also in the first direction DR1.

The plurality of second holes H2 is disposed in an area overlapping the plurality of reflection electrodes RE and is disposed so as not to overlap the plurality of light emitting diodes LED.

The plurality of third holes H3 is disposed in an outer periphery of the pixel PX, outward from the plurality of second holes H2. Referring to FIG. 7, the plurality of third holes H3 is disposed in one side of the second hole H2 in the first direction DR1.

The plurality of third holes H3 is disposed in an area which does not overlap the plurality of reflection electrodes RE and is disposed so as not to overlap the plurality of light emitting diodes LED. The adhesive layer 116 is disposed on the plurality of reflection electrodes RE and the insulating layer 119.

The adhesive layer 116 is coated on the front surface of the substrate 110 to fix the light emitting diode LED disposed on the adhesive layer 116. For example, the adhesive layer 116 may be selected from any one of adhesive polymer, epoxy resist, UV resin, polyimide, acrylate, urethane, and polydimethylsiloxane (PDMS), but is not limited thereto.

The adhesive layer 116 may be filled in the plurality of holes H. Accordingly, a thickness of the adhesive layer 116 in the plurality of holes H is larger than a thickness of the adhesive layer 116 on the insulating layer 119.

The adhesive layer 116 may cover top surfaces of the plurality of reflection electrodes RE and a top surface of the first planarization layer 115. Further, the adhesive layer extends from the top surface of the insulating layer 119 to cover a side surface of the insulating layer 119 disposed in the plurality of holes H. In the meantime, when ends of the plurality of reflection electrodes RE are disposed in the plurality of holes H, the adhesive layer 116 may also cover the ends of the plurality of reflection electrodes RE.

The adhesive layer 116 is formed by covering and curing a liquid organic insulating material on the insulating layer 119. Therefore, the organic insulating material having fluidity before the curing process flows to the plurality of holes H due to the step structure of the insulating layer 119 including the plurality of holes H. For example, the organic insulating material moves from the top surface of the insulating layer 119 in which the hole H is not disposed to a center direction of the pixel PX in which the plurality of holes H is disposed. Therefore, a thickness of the organic insulating material in a hole H which is disposed in an outer peripheral area in one pixel PX may be larger than a thickness of the organic insulating material in a hole H disposed in a center portion. Accordingly, when the adhesive layer 116 is formed with the organic insulating material by performing the curing process, the adhesive layer 116 may have a thickness which varies in every position of the hole H. A thickness of the adhesive layer 116 in a hole H which is disposed in an outer peripheral area in one pixel PX may be larger than a thickness of the adhesive layer 116 in a hole H disposed in a center portion. Therefore, the thickness of the adhesive layer 116 in the hole H disposed in the second area A2 is larger than the thickness of the adhesive layer 116 in the hole H disposed in the first area A1. Referring to FIG. 7, a thickness of a portion of the adhesive layer 116 overlapping the plurality of first holes H1 and the plurality of second holes H2 may be different from a thickness of a portion overlapping the plurality of third holes H3. Specifically, a thickness of a portion of the adhesive layer 116 overlapping the plurality of third holes H3 may be larger than a thickness of a portion overlapping the plurality of first holes H1 and the plurality of second holes H2. Further, a thickness of a portion of the adhesive layer 116 overlapping the plurality of first holes H1 may be different from a thickness of a portion overlapping the plurality of second holes H2.

Further, in each of the plurality of holes H, the adhesive layer 116 may be formed in an uneven shape. For example, there may be a thickness deviation of the adhesive layer 116 in each of the plurality of holes H. Specifically, in each of the plurality of holes H, a thickness of the adhesive layer 116 is increased toward the outer peripheral direction of the pixel PX. Referring to FIG. 7, the more adjacent to the third hole H3, the larger the thickness of the adhesive layer 116 in the second hole H2 and the more away from the second hole H2, the larger the thickness of the adhesive layer 116 in the third hole H3. The organic insulating material for forming the adhesive layer 116 flows from the outer periphery of the pixel PX to the center portion of the pixel PX. At this time, the organic insulating material may flow along a side surface of the insulating layer 119 disposed in the hole H. Accordingly, as the organic insulating material is adjacent to the side surface of the insulating layer 119 disposed in the outer peripheral area of the pixel PX, the organic insulating material is disposed to have a large thickness. Therefore, there may be a thickness deviation of the adhesive layer 116 in one hole H.

The thickness deviation of the adhesive layer 116 may vary depending on the shape of the plurality of holes H. For example, the adhesive layer 116 may flow along a side surface of the insulating layer 119 disposed in the plurality of holes H. Therefore, an amount of the adhesive layer 116 which is filled in the plurality of holes H may vary depending on an area of a side surface of the insulating layer 119. For example, an amount of the adhesive layer 116 flowing along the side surface of the insulating layer 119 in which long sides of the plurality of holes H are disposed is larger than an amount of the adhesive layer 116 flowing along the side surface of the insulating layer 119 in which short sides of the plurality of holes H are disposed. Accordingly, an amount of the adhesive layer 116 flowing in the first direction DR1 from the side surface of the insulating layer 119 in which long sides of the plurality of holes H are disposed is larger than an amount of the adhesive layer 116 flowing in the second direction DR2 from the side surface of the insulating layer 119 in which short sides of the plurality of holes H are disposed. Accordingly, referring to FIG. 6, the thickness deviation of the adhesive layer 116 in the second direction DR2 does not occur, but referring to FIG. 7, the thickness deviation of the adhesive layer 116 in the first direction DR1 may occur.

The adhesive layer 116 may include a contact hole which exposes the plurality of reflection electrodes RE. At this time, the plurality of connection electrodes CE and the plurality of light emitting diodes LED, and the plurality of reflection electrodes RE are electrically connected through a contact hole of the adhesive layer 116. The contact hole of the adhesive layer 116 may be disposed in an area overlapping the plurality of holes H. For example, referring to FIGS. 5 and 6, in an area overlapping the plurality of second holes H2, the adhesive layer 116 includes a contact hole which exposes the plurality of reflection electrodes RE. In the plurality of second holes H2, the plurality of light emitting diodes LED and the plurality of reflection electrodes RE are electrically connected.

The plurality of light emitting diodes LED is disposed in each of the plurality of sub pixels SP on the adhesive layer 116. For example, the plurality of light emitting diodes LED is disposed in the plurality of first holes H1. At this time, in the plurality of first holes H1, bottom surfaces of the plurality of light emitting diodes LED may be disposed to be lower than a top surface of the insulating layer 119.

The plurality of light emitting diodes LED is elements which emit light by a current and may include light emitting diodes LED which emit red light, green light, and blue light and implement various colored light including white by a combination thereof. For example, the plurality of light emitting diodes LED may be light emitting diodes (LED) or a micro LEDs, but is not limited thereto.

Each of the plurality of light emitting diodes LED includes a first semiconductor layer 121, an emission layer 122, a second semiconductor layer 123, a first electrode 124, a second electrode 125, and an encapsulation film 126.

Referring to FIGS. 5 to 7, a first semiconductor layer 121 of the light emitting diode LED is disposed on the adhesive layer 116 and a second semiconductor layer 123 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may be layers doped with n type and p type impurities into a material such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but is not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode which electrically connects the driving transistor DT and the first semiconductor layer 121. The first electrode 124 may be disposed on a top surface of the first semiconductor layer 121 which is exposed from the light emitting layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 is disposed on the top surface of the second semiconductor layer 123. The second electrode 125 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation film 126 which encloses the first semiconductor layer 121, the emission layer 122, the second semiconductor layer 123, the first electrode 124, and the second electrode 125 is disposed. The encapsulation film 126 is formed of an insulating material to protect the first semiconductor layer 121, the emission layer 122, and the second semiconductor layer 123. In the encapsulation film 126, a contact hole which exposes the first electrode 124 and the second electrode 125 is formed to electrically connect a first connection electrode CE1 and a second connection electrode CE2 to the first electrode 124 and the second electrode 125.

If the light emitting diode LED is a lateral structure or a flip-chip structure, the light emitting diode may be disposed along one direction of the first electrode 124 and the second electrode 125. Therefore, each of the plurality of light emitting diodes may have a long side in a direction in which the first electrode 124 and the second electrode 125 are disposed. For example, referring to FIG. 6, the third light emitting diode LED3 has a long side in the second direction DR2. For example, referring to FIG. 7, the third light emitting diode LED3 has a short side in the first direction DR1. However, it is not limited thereto and all the light emitting diodes LED may be formed to have the same side.

The second planarization layer 117 and the third planarization layer 118 are disposed on the adhesive layer 116. The second planarization layer 117 overlaps a part of side surfaces of the plurality of light emitting diodes LED to fix and protect the plurality of light emitting diodes LED. Specifically, even though in FIGS. 5 to 7, it is illustrated that the encapsulation film 126 encloses all the side surfaces of the first semiconductor layer 121, a part of the side surface of the first semiconductor layer 121 may be exposed from the encapsulation film 126. The light emitting diode LED manufactured on the wafer is separated from the wafer to be transferred onto the display panel PN. However, during the process of separating the light emitting diode LED from the wafer, a part of the encapsulation film 126 may be torn. For example, a part of the encapsulation film 126 which is adjacent to a lower edge of the first semiconductor layer 121 of the light emitting diode LED is torn during the process of separating the light emitting diode LED from the wafer. Accordingly, a part of a lower side surface of the first semiconductor layer 121 may be exposed to the outside. However, even though the lower portion of the light emitting diode LED is exposed from the encapsulation film 126, the first connection electrode CE1 and the second connection electrode CE2 are formed after forming the second planarization layer 117 which covers the side surface of the first semiconductor layer 121. Accordingly, a short defect may be minimized.

Further, the third planarization layer 118 is formed to cover upper portions of the second planarization layer 117 and the light emitting diode LED and a contact hole which exposes the first electrode 124 and the second electrode 125 of the light emitting diode LED may be formed. The first electrode 124 and the second electrode 125 of the light emitting diode LED are exposed from the third planarization layer 118 and the third planarization layer 118 is partially disposed in an area between the first electrode 124 and the second electrode 125 to minimize a short defect.

The second planarization layer 117 and the third planarization layer 118 may be configured by a single layer or a double layer, and for example, may be formed of photo resist or an acrylic organic material, but is not limited thereto. Even though in the specification, it is described that the second planarization layer 117 and the third planarization layer 118 are disposed, the planarization layer may be formed by a single layer, but is not limited thereto.

A plurality of connection electrodes CE is disposed on the third planarization layer 118. The plurality of connection electrodes CE includes a plurality of first connection electrodes CE1 and a second connection electrode CE2.

The first connection electrode CE1 is an electrode which is disposed in each of the plurality of sub pixels SP to electrically connect the light emitting diode LED and the driving transistor DT. The first connection electrode CE1 is connected to the first reflection electrode RE1 through the contact hole formed in the third planarization layer 118, the second planarization layer 117, and the adhesive layer 116. Accordingly, the first connection electrode CE1 is electrically connected to any one of the source electrode SE and the drain electrode DE of the driving transistor DT through the first reflection electrode RE1. The first connection electrode CE1 is connected to the first electrodes 124 of the plurality of light emitting diodes LED through a contact hole formed in the third planarization layer 118. Accordingly, the first connection electrode CE1 electrically connects the driving transistor DT to the first electrode 124 and the first semiconductor layer 121 of the plurality of light emitting diodes LED.

The second connection electrode CE2 is connected to the second reflection electrode RE2 through the contact hole formed in the third planarization layer 118, the second planarization layer 117, and the adhesive layer 116. The second connection electrode CE2 is connected to the second electrodes 125 of the plurality of light emitting diodes LED through a contact hole formed in the third planarization layer 118.

Even though in FIG. 7, it is illustrated that the plurality of connection electrodes CE is disposed so as not to overlap the third hole H3, the present disclosure is not limited thereto and the plurality of connection electrodes CE is disposed so as to overlap the third hole H3.

The bank BB is disposed on the third planarization layer 118. The bank BB may be disposed to be spaced apart from the light emitting diode LED with a predetermined interval.

The bank BB may be formed of an opaque material to reduce color mixture between the plurality of sub pixels SP and for example, may be formed of black resin, but is not limited thereto.

The bank BB has an open area in an area corresponding to the light emitting diode LED. Therefore, referring to FIGS. 5 to 7, the bank BB is disposed so as not to overlap the first hole H1 in which the plurality of light emitting diodes LED is disposed, among the plurality of holes H, and is disposed so as to overlap the second hole H2 and the third hole H3.

The protection layer 190 is disposed on the third planarization layer 118 and the bank BB. The protection layer 190 is a layer for protecting a configuration below the protection layer 190 and for example, covers at least a part of the light emitting diode LED. The protection layer 190 may be configured by a single layer or a double layer of transparent epoxy, silicon oxide (SiOx) or silicon nitride (SiNx), but is not limited thereto.

The optical film MF is disposed on the protection layer 190. The optical film MF may be a functional film which implements a higher quality of images while protecting the display apparatus 100. For example, the optical film MF may include an anti-scattering film, an anti-glare film, an anti-reflecting film, a low-reflecting film, an Oled transmittance controllable film, or a polarizer, but is not limited thereto.

An adhesive layer may be additionally disposed between the optical film MF and the protection layer 190. Alternatively, the optical film MF is also defined to include an adhesive layer disposed therebelow.

In the meantime, the first connection electrode CE1 which connects the driving transistor DT and the light emitting diode LED which are disposed in each of the plurality of sub pixels SP is individually disposed in each of the plurality of sub pixels SP.

In the meantime, the plurality of light emitting diodes LED may be connected to the plurality of power lines. For example, each of the plurality of light emitting diodes LED is connected to the plurality of power lines through the plurality of first connection electrodes CE1 and the plurality of second connection electrodes CE2.

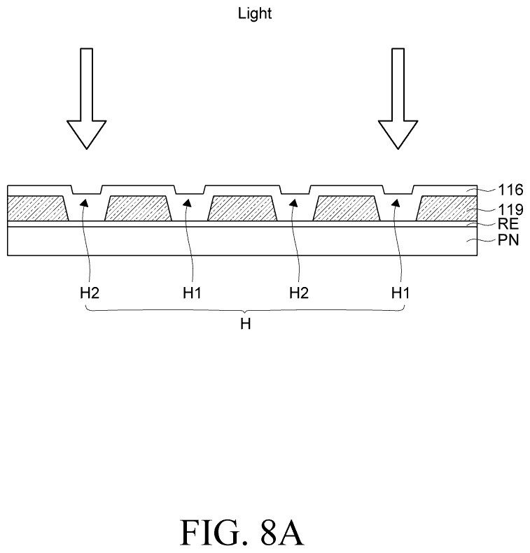

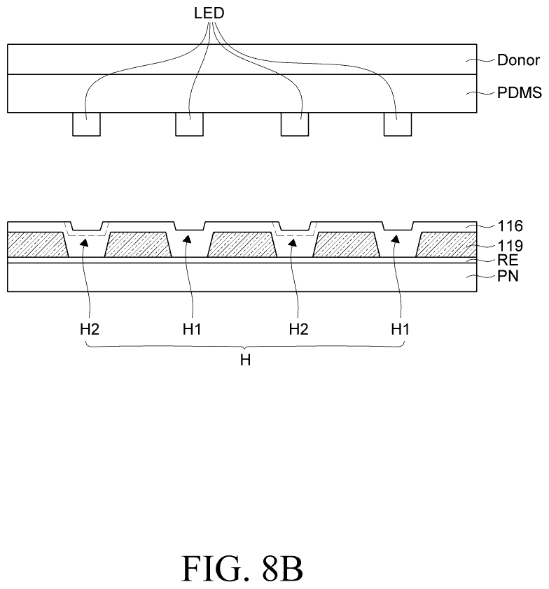

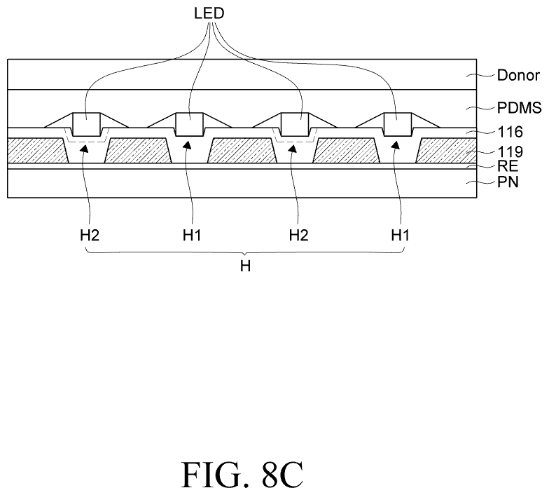

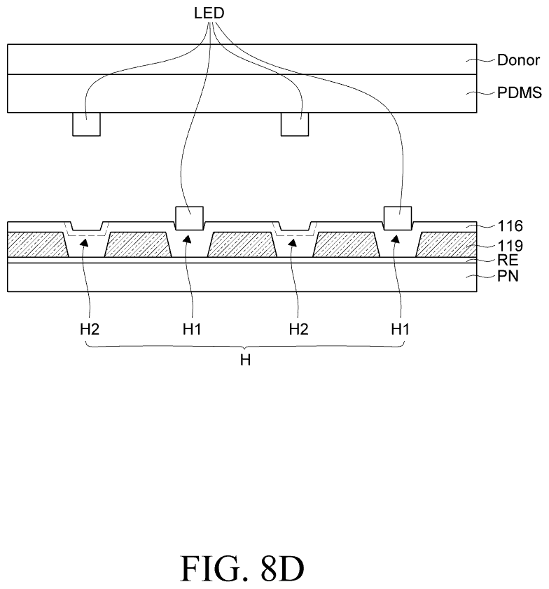

FIGS. 8A to 8D are process diagrams for explaining a manufacturing method of a display apparatus according to an exemplary embodiment of the present disclosure. FIGS. 8A to 8D are views for explaining a process of transferring a plurality of light emitting diodes LED onto the display panel PN using a donor.

Referring to FIG. 8A, a display panel PN on which a plurality of reflection electrodes RE, an insulating layer 119 including a plurality of holes H, and an adhesive layer 116 are sequentially laminated is prepared. At this time, in the plurality of holes H, a top surface of the adhesive layer 116 is formed to be lower than a top surface of the adhesive layer 116 above the insulating layer 119.

In order to perform the transfer process, light is selectively irradiated only in a partial area of the display panel PN to change an adhesive strength of the insulating layer 119. For example, light is irradiated so as to correspond to the second hole H2 to cure a surface of the adhesive layer 116 disposed in the second hole H2. Accordingly, the adhesive layer 116 disposed in the first hole H1 maintains an initial adhesive strength, but the adhesive layer 116 disposed in the second hole H2 may have an adhesive strength weaker than the initial adhesive strength.

Referring to FIG. 8B, a donor to which the plurality of light emitting diodes LED is attached is disposed on the display panel PN. The plurality of light emitting diodes LED is attached to the donor through an adhesive member PDMS. The adhesive member PDMS may be formed of a material having ductility.

In the meantime, the plurality of light emitting diodes LED may be aligned so as to correspond to the position of the plurality of holes H. For example, the light emitting diode LED which emits the same color light may be attached so as to correspond to each of the plurality of first holes H1. Further, the light emitting diode LED which emits the same color light may be attached so as to correspond to each of the plurality of second holes H2. In the meantime, the light emitting diode LED disposed to correspond to the first hole H1 and the light emitting diode disposed to correspond to the second hole H2 may be light emitting diodes which emit different color light.

Further, in FIG. 8B, in the adhesive layer 116 disposed in the second hole H2, surface curing is performed so that the adhesive strength is weaker than the initial adhesive strength and a surface of the adhesive layer 116 with a changed adhesive strength is illustrated with a dotted line.

Referring to FIG. 8C, after placing the donor on the display panel PN, a pressure is applied. At this time, the plurality of light emitting diodes LED attached to the donor is in contact with a top surface of the adhesive layer 116 of the display panel PN.

In the meantime, during the transfer process, a pressure occurs between the donor and the display panel PN to change a shape of the adhesive member PDMS. At this time, the plurality of holes H minimizes the shape change of the adhesive member PDMS to suppress the over-transferring problem. The plurality of light emitting diodes LED attached to the donor is disposed to be lower than a top surface of the insulating layer 119 in an area overlapping the plurality of holes H. Therefore, as compared with a case that the insulating layer does not include the plurality of holes, in an area corresponding to the plurality of holes H, the shape change of the adhesive member PDMS is minimized. Accordingly, a pressure between the light emitting diode LED and the adhesive member PDMS is reduced. Therefore, the pressure between the donor and the display panel PN is reduced and the over-transferring problem may be suppressed.

Referring to FIG. 8D, the donor is separated from the display panel PN. Some light emitting diode LED among the plurality of light emitting diodes LED is attached to the adhesive layer 116 to be transferred onto the display panel PN and some light emitting diode LED, among the plurality of light emitting diodes LED attached to the donor is separated from the adhesive layer 116 while maintaining an attached state to the donor. For example, the adhesive layer 116 disposed in the first hole H1 is in a state that the initial adhesive strength is maintained. Therefore, the light emitting diode LED attached onto the top surface of the adhesive layer 116 in the first hole H1 is attached to an adhesive layer 116 having a strong adhesive strength to be separated from the donor. In contrast, the adhesive layer 116 disposed in the second hole H2 may be a state having an adhesive strength smaller than the initial adhesive strength. Therefore, the light emitting diode LED attached onto the top surface of the adhesive layer 116 in the second hole H2 is in contact with a top surface of the adhesive layer 116 having a weaker adhesive strength and then is separated from the display panel PN together with the donor when the donor is separated from the display panel PN.

The donor to which only some light emitting diode LED, among the plurality of light emitting diodes LED, is attached is in contact with the display panel PN again in a next transfer process. Accordingly, the light emitting diode LED attached to the donor is transferred onto the display panel PN through a plurality of transfer processes. For example, light emitting diodes LED which emit different color light are attached to the plurality of donors and in one transfer process, only light emitting diodes LED which emit the same color light are transferred onto the display panel PN.

The adhesive layer is formed by curing a liquid organic insulating material so that there may be a thickness deviation in an area where a step is generated. For example, when the insulating layer disposed below the adhesive layer includes a plurality of holes, a thickness of the hole disposed in the outermost periphery of each of the plurality of pixels is larger than a thickness of a hole disposed in a center portion of each of the plurality of pixels. In the meantime, when the thickness of the adhesive layer is increased, an over-transferring problem may be caused in the transfer process. For example, when the thickness of the adhesive layer is increased, a pressure generated between the donor and the display panel may be increased. Accordingly, even though the light emitting diode is in contact with an adhesive layer having a weak adhesive strength during the transfer process, the light emitting diode may be transferred onto the display panel. Accordingly, an over-transferring problem in that a light emitting diode which needs to be transferred in a next process is transferred onto the display panel may occur. Accordingly, when the adhesive layer is formed to be thick in a hole disposed in the outermost periphery of each of the plurality of pixels, the over-transferring problem may occur in an area corresponding to the outer peripheral area of the pixel.

Therefore, in the display apparatus 100 according to the exemplary embodiment of the present disclosure, a dummy type third hole H3 is formed in the outermost periphery of each of the plurality of pixels PX. Accordingly, the plurality of third holes H3 serves as wells and suppresses an appropriate amount or more of an uncured adhesive layer 116 from flowing to the first hole H1 and the second hole H2 in an area having a high peripheral step. Therefore, the plurality of third holes H3 minimizes the thickness deviation of the adhesive layer 116 in the first hole H1 and the second hole H2.

In the meantime, when there is no thickness deviation of the adhesive layer 116 in the first hole H1 and the second hole H2, a pressure generated between the donor and the plurality of light emitting diodes LED during the transfer process may be reduced. Therefore, the over-transferring problem in that a light emitting diode which needs to be transferred in a next transfer process, among the plurality of light emitting diodes LED attached to the donor is disposed in the second hole H2 is suppressed. Accordingly, in the display apparatus 100 according to the exemplary embodiment of the present disclosure, a transfer/non-transfer selectivity of the light emitting diode LED is increased in the manufacturing process of the display apparatus 100. Further, even though the transfer process is performed using a donor with a large area plural times, the transfer success rate of the light emitting diode LED is increased to reduce a process cost and a product cost.

Further, in the display apparatus 100 according to the exemplary embodiment of the present disclosure, the plurality of third holes H3 is disposed to be adjacent to a surface in which long sides of the plurality of first holes H1 and the plurality of second holes H2 are disposed. An amount of the adhesive layer 116 flowing along the side surface of the insulating layer 119 in which short sides of the plurality of holes H are disposed is larger than an amount of the adhesive layer 116 flowing along the side surface of the insulating layer 119 in which long sides of the plurality of holes H are disposed. Accordingly, in the display apparatus 100 according to the exemplary embodiment of the present disclosure, the plurality of third holes H3 is disposed on a surface on which long sides of the plurality of first holes H1 and the plurality of second holes H2 are disposed. Therefore, an appropriate amount or more of the adhesive layer 116 is effectively suppressed from overflowing to the first hole H1 and the second hole H2. Accordingly, in the display apparatus 100 according to the exemplary embodiment of the present disclosure, the transfer success rate of the light emitting diode LED is increased to reduce the process cost and the product cost.

Further, in the display apparatus 100 according to the exemplary embodiment of the present disclosure, the plurality of third holes H3 may have the same size as the plurality of first holes H1 and the plurality of second holes H2. If the plurality of third holes has a larger size than the plurality of first holes and the plurality of second holes, all the adhesive layer flowing in the outer peripheral area of the pixel may be filled in the plurality of third holes. Therefore, the adhesive layer may not flow in the plurality of first holes and the plurality of second holes. In contrast, when the plurality of third holes has a size smaller than that of the plurality of first holes and the plurality of second holes, the adhesive layer flows from the plurality of third holes to the plurality of first holes and the plurality of second holes. Therefore, there may be a thickness deviation in the plurality of first holes and the plurality of second holes. Accordingly, in the display apparatus 100 according to the exemplary embodiment of the present disclosure, the plurality of third holes H3 is disposed to have the same size as the plurality of first holes H1 and the plurality of second holes H2 to suppress the thickness deviation of the adhesive layer 116. Further, the transfer success rate is increased to reduce the process cost and the product cost.

Further, in the display apparatus 100 according to the exemplary embodiment of the present disclosure, the plurality of third holes H3 is disposed in an area which does not overlap the reflection electrode RE to improve the reliability. For example, during the process of connecting the plurality of wiring lines and the plurality of reflection electrodes disposed on the display panel, a dry etching process is performed on the plurality of reflection electrodes. At this time, when the reflection electrode is exposed from the plurality of third holes, arc phenomenon may occur in the reflection electrode so that the reliability of the reflection electrode is degraded. Accordingly, the plurality of third holes H is disposed in an area which does not overlap the reflection electrode RE to improve the reliability of the display apparatus 100.

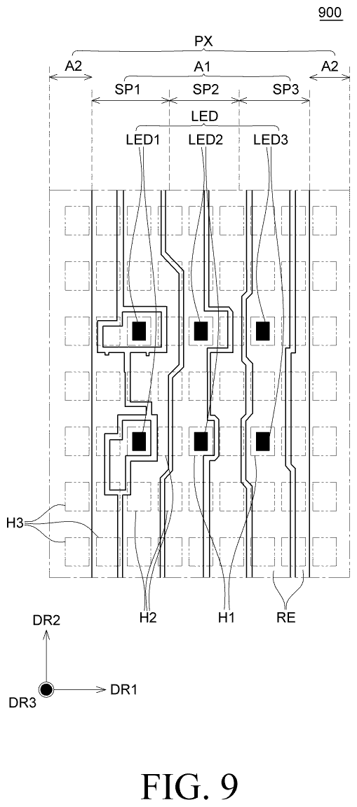

FIG. 9 is an enlarged plan view of a display apparatus according to an exemplary embodiment of the present disclosure. The only difference between the display apparatus 900 of FIG. 9 and the display apparatus 100 of FIGS. 1 to 7 is a plurality of third holes H3, but the other configurations are substantially the same, so that a redundant description will be omitted.

Referring to FIG. 9, in each of the plurality of pixels PX, an insulating layer including a plurality of holes H is disposed on the plurality of reflection electrodes RE.

The plurality of holes H includes a plurality of first holes H1, a plurality of second holes H2, and a plurality of third holes H3. The plurality of first holes H1 and the plurality of second holes H2 may be disposed in the first area A1. In the meantime, the plurality of third holes H3 is disposed in an outer periphery of the pixel PX, outward from the plurality of second holes H2.

The plurality of third holes H3 is disposed in the outermost periphery of each pixel PX in the first direction DR1. For example, the plurality of third holes H3 is disposed in the second area A2. Therefore, in the first direction DR1, the third hole H3, the second hole H2, and the first hole H1 are sequentially disposed along a center direction of a pixel PX from an outermost periphery of the pixel PX or the plurality of third holes H3 is disposed with the plurality of second holes H2 therebetween.

Further, the plurality of third holes H3 in the second area A2 is disposed so as not to overlap the plurality of reflection electrodes RE.

Further, the plurality of third holes H3 may be disposed in the outermost periphery of each pixel PX in the second direction DR2. For example, in the first area A1, the plurality of third holes H3 is disposed in an outermost periphery of the pixel PX, outward from the plurality of second holes H2. Therefore, in the second direction DR2, the third hole H3, the second hole H2, and the first hole H1 are sequentially disposed along a center direction of a pixel PX from an outermost periphery of the pixel PX or the plurality of third holes H3 is disposed with the plurality of second holes H2 therebetween.

Further, the plurality of third holes H3 in the first area A1 is disposed so as to overlap the plurality of reflection electrodes RE.

In the meantime, the plurality of third holes H3 may be continuously disposed along the first direction DR1 and/or the second direction DR2. For example, in one pixel PX, the plurality of third holes H3 may be continuously disposed along the first direction DR1 and/or the second direction DR2 so as to enclose the plurality of second holes H2 and the plurality of first holes H1.

Therefore, in the display apparatus 900 according to another exemplary embodiment of the present disclosure, a dummy type third hole H3 is formed in the outermost periphery of each of the plurality of pixels PX. Therefore, the plurality of third holes H3 serves as a well and minimizes the thickness deviation of the adhesive layer 116 in the first hole H1 and the second hole H2. Therefore, the over-transferring problem in that the light emitting diode LED is disposed on the second hole H2 is suppressed and the transfer success rate of the light emitting diode LED is increased to reduce the process cost and the product cost.

In the display apparatus 900 according to another exemplary embodiment of the present disclosure, the plurality of third holes H3 is disposed to be adjacent to a surface in which long sides of the plurality of first holes H1 and the plurality of second holes H2 are disposed. Accordingly, an appropriate amount or more of the adhesive layer 116 is effectively suppressed from overflowing to the first hole H1 and the second hole H2 to increase the transfer success rate of the light emitting diode LED and reduce the process cost and the product cost.

Further, in the display apparatus 900 according to another exemplary embodiment of the present disclosure, the plurality of third holes H3 may have the same size as the plurality of first holes H1 and the plurality of second holes H2. Accordingly, the thickness deviation of the adhesive layer 116 is suppressed and the transfer success rate of the light emitting diode LED is increased to reduce the process cost and the product cost.

Further, in the display apparatus 900 according to another exemplary embodiment of the present disclosure, the plurality of third holes H3 is disposed to be adjacent to a surface in which short sides of the plurality of first holes H1 and the plurality of second holes H2 are disposed. Accordingly, the adhesive layer 116 is suppressed from overflowing along the side surface of the insulating layer 119 on which short sides of the plurality of holes H are disposed and overflowing of an appropriate amount or more to the first hole H1 and the second hole H2 is effectively suppressed. Accordingly, in the display apparatus 900 according to another exemplary embodiment of the present disclosure, the transfer success rate of the light emitting diode LED is increased to reduce the process cost and the product cost.

The exemplary embodiments of the present disclosure can also be described as follows:

According to an aspect of the present disclosure, there is provided a display apparatus. The display apparatus comprises a substrate in which a plurality of pixels including a plurality of sub pixels is defined, a plurality of transistors disposed on the substrate, an insulating layer disposed on the substrate, an adhesive layer disposed on the insulating layer, and a plurality of light emitting diodes disposed on the adhesive layer in each of the plurality of sub pixels, wherein the insulating layer includes a plurality of holes disposed in each of the plurality of pixels, the plurality of holes includes a plurality of first holes, a plurality of second holes, and a plurality of third holes, the plurality of first holes is disposed so as to overlap the plurality of light emitting diodes, the plurality of second holes is disposed so as to enclose the plurality of first holes on a plane, and the plurality of third holes includes a hole disposed in the outermost periphery in a first direction, among the plurality of holes.

Each of the plurality of holes may have a short side in the first direction and a long side in a second direction.

Each of the plurality of light emitting diode may have a long side in the second direction.

The display apparatus may further comprise a plurality of reflection electrodes disposed between the substrate and the insulating layer, wherein the plurality of first holes and the plurality of second holes may overlap the plurality of reflection electrodes and the plurality of third holes does not overlap the plurality of reflection electrodes.

In an area overlapping the plurality of second holes, the adhesive layer may include a hole which exposes the plurality of reflection electrodes and in the hole, the plurality of reflection electrodes and the plurality of light emitting diodes may be electrically connected.

A thickness of a portion of the adhesive layer which overlaps the plurality of first holes and the plurality of second holes may be different from a thickness of a portion which overlaps the plurality of third holes.

The thickness of the portion of the adhesive layer which overlaps the plurality of third holes may be larger than the thickness of the portion which overlaps the plurality of first holes and the plurality of second holes.

The thickness of the portion of the adhesive layer which overlaps the plurality of first holes may be different from the thickness of a portion which overlaps the plurality of second holes.

The display apparatus may further comprise a bank disposed above the plurality of light emitting diodes, wherein the plurality of first holes may not overlap the bank and the plurality of second holes and the plurality of third holes may overlap the bank.

The plurality of third holes may further include a hole disposed in the outermost periphery in a second direction.

According to another aspect of the present disclosure, there is provided a display apparatus. The display apparatus comprises a substrate in which a pixel including a plurality of sub pixels is defined, an insulating layer disposed on the substrate, a plurality of reflection electrodes disposed on the insulating layer, an adhesive layer disposed on the plurality of reflection electrodes, and a plurality of light emitting diodes disposed on the adhesive layer in each of the plurality of sub pixels, wherein the insulating layer includes a plurality of first holes overlapping the plurality of reflection electrodes, a plurality of second holes overlapping the plurality of reflection electrodes and a plurality of third holes which does not overlap the plurality of reflection electrodes.

A thickness of the adhesive layer which overlaps the plurality of third holes may be larger than a thickness of the adhesive layer which overlaps the plurality of first holes and the plurality of second holes.

The plurality of first holes may overlap the plurality of light emitting diodes, and the plurality of second holes and the plurality of third holes may not overlap the plurality of light emitting diodes

The plurality of third holes may be disposed in the outermost periphery of each of the plurality of pixels in a first direction.

The plurality of second holes may be disposed so as to enclose one first hole, among the plurality of first holes and the plurality of third holes may be disposed in the outermost periphery in each of the plurality of pixels, outward from the plurality of second holes.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate in which a plurality of pixels including a plurality of sub pixels is defined;
a plurality of transistors disposed on the substrate;
an insulating layer disposed on the substrate;
an adhesive layer disposed on the insulating layer; and
a plurality of light emitting diodes disposed on the adhesive layer in each of the plurality of sub pixels,
wherein the insulating layer includes a plurality of holes disposed in each of the plurality of pixels, the plurality of holes includes a plurality of first holes, a plurality of second holes, and a plurality of third holes, the plurality of first holes is disposed so as to overlap the plurality of light emitting diodes, and
wherein the plurality of second holes is disposed so as to enclose the plurality of first holes on a plane, and the plurality of third holes includes a hole disposed in an outermost periphery in a first direction, among the plurality of holes.

2. The display apparatus according to claim 1, wherein each of the plurality of holes has a short side in the first direction and a long side in a second direction different from the first direction.

3. The display apparatus according to claim 2, wherein each of the plurality of light emitting diodes has a long side in the second direction.

4. The display apparatus according to claim 1, further comprising:
a plurality of reflection electrodes disposed between the substrate and the insulating layer,
wherein the plurality of first holes and the plurality of second holes overlap the plurality of reflection electrodes and the plurality of third holes does not overlap the plurality of reflection electrodes.

5. The display apparatus according to claim 4, wherein in an area overlapping the plurality of second holes, the adhesive layer includes a contact hole which exposes the plurality of reflection electrodes and in the contact hole, the plurality of reflection electrodes and the plurality of light emitting diodes are electrically connected.

6. The display apparatus according to claim 1, wherein a thickness of a portion of the adhesive layer which overlaps the plurality of first holes and the plurality of second holes is different from a thickness of a portion which overlaps the plurality of third holes.

7. The display apparatus according to claim 6, wherein the thickness of the portion of the adhesive layer which overlaps the plurality of third holes is larger than the thickness of the portion which overlaps the plurality of first holes and the plurality of second holes.

8. The display apparatus according to claim 7, wherein the thickness of the portion of the adhesive layer which overlaps the plurality of first holes is different from the thickness of a portion which overlaps the plurality of second holes.

9. The display apparatus according to claim 1, further comprising:
a bank disposed above the plurality of light emitting diodes,
wherein the plurality of first holes does not overlap the bank and the plurality of second holes and the plurality of third holes overlap the bank.

10. The display apparatus according to claim 1, wherein the plurality of third holes further includes a hole disposed in an outermost periphery in a second direction.

11. The display apparatus according to claim 1, wherein in the first direction, the plurality of third holes, the plurality of second holes, and the plurality of first holes are sequentially disposed along a center direction of each of the plurality of pixels from an outermost periphery of each of the plurality of pixels.

12. The display apparatus according to claim 1, wherein the plurality of third holes have the same size as the plurality of first holes and the plurality of second holes.

13. A display apparatus, comprising:
a substrate in which a plurality of pixels including a plurality of sub pixels is defined;
an insulating layer disposed on the substrate;
a plurality of reflection electrodes disposed on the insulating layer;
an adhesive layer disposed on the plurality of reflection electrodes; and
a plurality of light emitting diodes disposed on the adhesive layer in each of the plurality of sub pixels,
wherein the insulating layer includes:
a plurality of first holes overlapping the plurality of reflection electrodes;
a plurality of second holes overlapping the plurality of reflection electrodes; and
a plurality of third holes which does not overlap the plurality of reflection electrodes.

14. The display apparatus according to claim 13, wherein a thickness of a portion of the adhesive layer which overlaps the plurality of third holes is larger than a thickness of a portion of the adhesive layer which overlaps the plurality of first holes and the plurality of second holes.

15. The display apparatus according to claim 13, wherein the plurality of first holes overlaps the plurality of light emitting diodes, and the plurality of second holes and the plurality of third holes do not overlap the plurality of light emitting diodes.

16. The display apparatus according to claim 13, wherein the plurality of third holes is disposed in an outermost periphery of each of the plurality of pixels in a first direction.

17. The display apparatus according to claim 13, wherein the plurality of second holes is disposed so as to enclose one first hole, among the plurality of first holes and the plurality of third holes is disposed in an outermost periphery in each of the plurality of pixels, outward from the plurality of second holes.

18. A display apparatus, comprising:
a substrate in which a plurality of pixels including a plurality of sub pixels is defined;
an insulating layer disposed on the substrate;
a plurality of reflection electrodes disposed on the insulating layer;
an adhesive layer disposed on the plurality of reflection electrodes; and
a plurality of light emitting diodes disposed on the adhesive layer in each of the plurality of sub pixels,
wherein the insulating layer includes:
a plurality of first holes overlapping the plurality of reflection electrodes;
a plurality of second holes overlapping the plurality of reflection electrodes; and
a plurality of third holes formed in an outermost periphery of each of the plurality of pixels.

19. The display apparatus according to claim 18, wherein, in a first direction, the plurality of third holes, the plurality of second holes, and the plurality of first holes are sequentially disposed along a center direction of each of the plurality of pixels from the outermost periphery of each of the plurality of pixels.

20. The display apparatus according to claim 19, wherein, in a second direction different from the first direction, the plurality of third holes, the plurality of second holes, and the plurality of first holes are sequentially disposed along a center direction of each of the plurality of pixels from the outermost periphery of each of the plurality of pixels.
